(19) United States
(12) Patent Application Publication
(10) Pub. No.: US 2024/0222161 A1
(43) Pub. Date: Jul. 4, 2024

(54) BLUE LASER ANNEALING EQUIPMENT AND ANNEALING MANUFACTURING PROCESS USING THE SAME

(71) Applicant: ADRC. CO. KR, Seoul (KR)

(72) Inventors: Jun Hyuk CHEON, Seoul (KR); Seongbok Kang, Gumi-si (KR); Jin-han Park, Gumi-si (KR)

(21) Appl. No.: 18/387,117

(22) Filed: Nov. 6, 2023

(30) Foreign Application Priority Data
Jan. 2, 2023 (KR) 10-2023-0000386

(51) Int. Cl. H01L 21/67; H01L 21/268; H01S 5/02251; H01S 5/02253; H01S 5/02255; H01S 5/40

(52) U.S. Cl. CPC H01L 21/67115; H01L 21/268; H01S 5/02251; H01S 5/02253; H01S 5/02255; H01S 5/4025

(57) ABSTRACT

The present disclosure relates to blue laser annealing equipment and an annealing manufacturing process using the same. The blue laser annealing equipment includes at least one blue laser diode controller including at least one output fiber; at least one light path module connected to an output fiber of the blue laser diode controller to process light emitted from the output fiber and direct the light to a substrate and perform a dehydrogenation process or a crystallization process on a silicon layer applied to the substrate; and a stage capable of relative motion with respect to the light path module and loading the substrate so that the dehydrogenation process and the crystallization process are performed on a surface of the substrate with respect to the light path module.

### CROSS-REFERENCE TO RELATED APPLICATION

This application claims priority to and the benefit of Korean Patent Application No. 10-2023-000386 filed in the Korean Intellectual Property Office on Jan. 2, 2023, the entire contents of which are incorporated herein by reference.

### BACKGROUND

### (a) Technical Field

The present disclosure relates to blue laser annealing equipment and an annealing manufacturing process using the same.

### (b) Description of the Related Art

A thin film transistor has a semiconductor layer having polycrystalline silicon. To provide the semiconductor layer having polycrystalline silicon, a hydrogenated amorphous silicon layer is applied to a substrate, a dehydrogenated amorphous silicon layer is obtained through a dehydrogenation process thereon, and then, polycrystalline (poly) silicon is obtained through a laser annealing operation.

When a crystallization process is performed while hydrogen is included, the hydrogen explodes and burns, and thus, the dehydrogenation process is essential. In the related art, to perform the dehydrogenation process, a process of placing the substrate coated with the hydrogenated amorphous silicon layer in a furnace and heating the substrate for about 2 hours in an atmosphere of about 450° C. was essential.

However, in this case, there were problems in that a process time increases and a manufacturing cost increases because the heating process and the crystallization process were separated.

### SUMMARY OF THE INVENTION

The present disclosure attempts to provide blue laser annealing equipment capable of simplifying a process by performing a dehydrogenation process and a crystallization process by using one annealing equipment without performing the dehydrogenation process in a separate location, and an annealing manufacturing process using the same.

According to the present embodiment, a blue laser annealing equipment includes at least one blue laser diode controller including at least one output fiber; at least one light path module connected to an output fiber of the blue laser diode controller to process light emitted from the output fiber and direct the light to a substrate and perform a dehydrogenation process or a crystallization process on a silicon layer applied to the substrate; and a stage capable of relative motion with respect to the light path module and loading the substrate so that the dehydrogenation process and the crystallization process are performed on a surface of the substrate with respect to the light path module.

The blue laser diode controller includes a controller housing; a plurality of blue laser diodes provided in the controller housing; a first focus lens disposed in front of each of the blue laser diodes; a prism lens reflecting light emitted from the first focus lens; a second focus lens focusing the light reflected from the prism lens and merged; and an image lens guiding the light emitted from the second focus lens to the output fiber.

The light path module includes a collimator connected to the output fiber; a light guide connected to the collimator; a polarization mirror reflecting light emitted from the light guide; and a projection lens module refracting and focusing the light reflected and emitted from the polarization mirror and irradiating the light onto the substrate placed on the stage.

The blue laser annealing equipment further includes a mirror actuator adjusting a reflection angle of the polarization mirror.

The blue laser diode controller is configured as one blue laser diode controller, the light path module is also configured as one light path module, and a reflection angle of the polarization mirror of the light path module is adjusted by an actuator.

An angle of the polarization mirror during a dehydrogenation process and an angle of the polarization mirror during a crystallization process are different from each other so that an output value and temperature of light energy from the light path module are different.

The blue laser diode controller is configured as two blue laser diode controllers, the two laser diode controllers are configured as a first laser diode controller of a high output and a second laser diode controller of a low output, and the light path module is configured as one light path module so that a reflection angle of the polarization mirror of the light path module is adjusted by an actuator.

During a dehydrogenation process, light enters the light path module from the second laser diode controller of the low output to perform the dehydrogenation process on a substrate, and during a crystallization process, light enters the light path module from the first laser diode controller of the high output to perform the crystallization process on the substrate.

The blue laser diode controller is configured as one blue laser diode controller, the light path module is configured as two light path modules and includes a first light path module for dehydrogenation and a second light path module for crystallization, and an inclination angle of a mirror of the first light path module is greater than an inclination angle of a mirror of the second light path module so that a temperature and output of light energy emitted from the first light path module are lower than a temperature and power of light energy emitted from the second light path module.

A first mirror of the first light path module and a second mirror of the second light path module are disposed adjacent to each other, light emitted from a light guide is partially reflected by the first mirror, and the remaining light moves to the second mirror through the first mirror and is reflected by the second mirror, the light reflected from the first mirror is used in a dehydrogenation process through a first projection lens module of a first light path module, and the light reflected from the second mirror is used in a crystallization process through a second projection lens module of a second light path module.

The blue laser diode controller is configured as two blue laser diode controllers, and the two laser diode controllers are configured as a first laser diode controller of a high output and a second laser diode controller of a low output, the light path module is configured as two light path modules and includes a first light path module for dehydrogenation and a second light path module for crystallization, the first laser diode controller and the second light path module are connected to each other, the second laser diode controller and the first light path module are connected to each other, and an inclination angle of a mirror of the first light path module is greater than an inclination angle of a mirror of the second light path module so that a temperature and output of light energy emitted from the first light path module are lower than a temperature and power of light energy emitted from the second light path module.

According to another aspect of the present embodiment, an annealing manufacturing process using a blue laser annealing equipment includes outputting light from a blue laser diode controller to at least one output fiber; performing a dehydrogenation process by reflecting the output light to a mirror and irradiating the light onto an amorphous silicon layer by controlling an inclination angle of the mirror to a first angle; and performing a crystallization process by irradiating the output light onto an area where the dehydrogenation process has been completed by controlling the inclination angle of the mirror to a second angle.

According to the embodiment, the process of performing the dehydrogenation process in the furnace is omitted, and the dehydrogenation process and the crystallization process may be performed in one equipment by using annealing equipment, and thus, the process may be simplified, thereby reducing the overall process time, and reducing the manufacturing cost.

In addition, according to the embodiment, stable and rapid dehydrogenation process and crystallization process are possible in a coplanar structure as well as stable and rapid dehydrogenation process and crystallization process are possible without a thermal damage even in an inverted staggered structure in which a gate insulating film is stacked below a silicon layer.

### BRIEF DESCRIPTION OF THE DRAWINGS

FIG. 1 is a perspective view of a state in which a light path module faces a substrate in the present embodiment.

FIG. 2 is a perspective view of a state in which the light path module deviates from the substrate in the present embodiment.

FIG. 3 is a perspective view of one side surface of the present embodiment.

FIG. 4 is an enlarged perspective view of FIG. 3.

FIG. 5 is a perspective view of another side surface of the present embodiment.

FIG. 6 is a diagram for explaining a dehydrogenation process of annealing equipment according to a first embodiment.

FIG. 7 is a diagram for explaining a crystallization process of the annealing equipment according to the first embodiment.

FIG. 8 is a diagram for explaining a dehydrogenation process of annealing equipment according to a second embodiment.

FIG. 9 is a diagram for explaining a crystallization process of the annealing equipment according to the second embodiment.

FIG. 10 is a diagram for explaining a dehydrogenation process and a crystallization process of annealing equipment according to a third embodiment.

FIG. 11 is a diagram for explaining a dehydrogenation process and a crystallization process of annealing equipment according to a fourth embodiment.

FIG. 12 is a schematic plan view of the annealing equipment according to the fourth embodiment.

FIG. 13 is a diagram for explaining a dehydrogenation process and a crystallization process of annealing equipment according to a fifth embodiment.

FIG. 14 is a schematic diagram of a blue laser diode controller.

FIG. 15 is a control block diagram of the present embodiment.

FIGS. 16a to 16l are process schematic diagrams of the present embodiment.

FIG. 17a is a diagram illustrating an example of a thin film transistor including a semiconductor layer crystallized according to the present embodiment.

FIG. 17b is a diagram illustrating another example of a thin film transistor including a semiconductor layer crystallized according to the present embodiment.

FIG. 18a is a characteristic graph of a thin film transistor including a semiconductor layer manufactured according to a comparative example heated at 450° C. for 2 hours in a furnace.

FIG. 18b is a characteristic graph of a coplanar structure thin film transistor including a semiconductor layer manufactured according to the present embodiment.

FIG. 18c is a characteristic graph of an inverted staggered structure thin film transistor including a semiconductor layer manufactured according to the present embodiment.

FIG. 19 is a photograph of a grain size for each thickness in the present embodiment.

### DETAILED DESCRIPTION OF THE EMBODIMENTS

Hereinafter, with reference to the accompanying drawings, various embodiments of the present disclosure will be described in detail so that those skilled in the art may easily carry out the present disclosure. The present disclosure may be embodied in many different forms and is not limited to the embodiments set forth herein.

In order to clearly explain the invention, parts irrelevant to the description are omitted, and the same reference numerals are used for the same or similar elements throughout the specification.

In addition, the accompanying drawings are only for easy understanding of the embodiments disclosed in the present specification, the technical idea disclosed in the present specification is not limited by the accompanying drawings, and should be understood to include all changes, equivalents or substitutes included in the spirit and technical scope of the present disclosure.

Since the size and thickness of each component shown in the drawings are arbitrarily shown for convenience of description, the present disclosure is not necessarily limited to those shown. In the drawings, the thickness of layers, films, panels, regions, etc., are exaggerated for clarity. Also, in the drawings, for convenience of explanation, the thicknesses of some layers and regions are exaggerated.

In addition, it will be understood that when an element such as a layer, film, region, or substrate is referred to as being “on” another element, it may be directly on the other element or intervening elements may also be present. In contrast, when an element is referred to as being “directly on” another element, there are no intervening elements present. In addition, being “above” or “on” a reference part means being located above or below the reference part, and does not necessarily mean being located “above” or “on” in the opposite direction of gravity.

In addition, unless explicitly described to the contrary, the word “comprise”, and variations such as “comprises” or “comprising”, will be understood to imply the inclusion of stated elements but not the exclusion of any other elements.

In addition, throughout the specification, when it is “on a plane” means when a target portion is viewed from above, and when it is “on a cross section” means when a cross section obtained by vertically cutting a target portion is viewed from the side.

In addition, throughout the specification, being “connected” does not only mean that two or more elements are directly connected, but may mean that two or more elements are indirectly connected through other elements, physically connected as well as electrically connected, or referred to by different names according to theirs locations or functions but are integral.

Hereinafter, various embodiments and modifications will be described in detail with reference to the drawings.

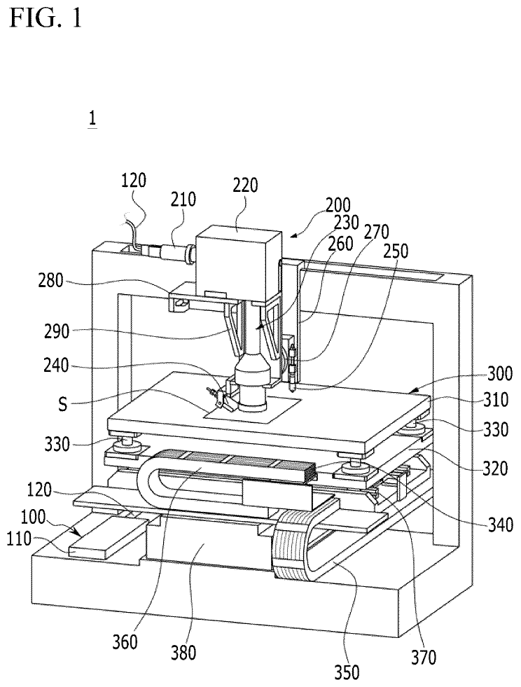

As shown in FIG. 1, blue laser annealing equipment (hereinafter referred to as ‘annealing equipment’) 1 according to the present embodiment includes a blue laser diode controller (hereinafter referred to as ‘laser controller’) 100.

A plurality of blue laser diodes are provided inside the laser controller 100, and at least one output fiber 120 is connected to a housing 110 of the laser controller 100.

The output fiber 120 is connected to a light path module 200 and may be configured as a single output fiber or more multi output fibers.

The light path module 200 processes light emitted from the output fiber 120 and directs the light to a substrate S to perform a dehydrogenation process and a crystallization process on an amorphous silicon layer applied on the substrate S.

A stage 300 is provided below the light path module 200, and the stage 300 is capable of relative motion on the light path module 200.

When a laser light is irradiated to the substrate S from the light path module 200 in a state in which the substrate S is loaded, the stage 300 serves to move the substrate S so that the dehydrogenation process and the crystallization process may be performed on the entire substrate S while moving a position of the substrate S back and forth and left and right below the light path module 200.

In the overall structure of the annealing equipment 1 according to the present embodiment, the laser controller 100 may be provided in a front left lower region in the drawing, and the stage 300 may be disposed in the middle of an inner space of the annealing equipment 1 in the drawing. A position of each of the laser controller 100 and the stage 300 shown in the drawing is an example for explaining an embodiment, but the invention is not limited thereto.

The laser light output from the laser controller 100 is a blue laser beam emitted from a blue diode, and may use a blue laser having a wavelength of about 360 nm to about 480 nm. More specifically, blue laser annealing may use a blue laser having a wavelength of about 440 nm to about 460 nm.

Blue laser annealing may be performed by scanning a blue laser line beam having a cross section defined by a width (horizontal) of 50 μm or less and a length (vertical) of 300 μm or more on a substrate surface in a direction orthogonal to a substrate moving direction. However, the shape of the blue laser line beam is not limited thereto. For example, blue laser annealing may be performed by scanning a blue laser beam having a point, circular, or polygonal shape on the substrate surface in a direction perpendicular to the substrate moving direction.

The exterior of the laser controller 100 is configured as the housing 110, the at least one output fiber 120 is connected to one side of the housing 110, and the output fiber 120 is connected to a collimator 210 provided in the light path module 200.

In the present embodiment, the entire housing surrounding the annealing equipment 1 is omitted.

The stage 300 is capable of relative movement on the light path module 200 in a state where the light path module 200 is fixed. That is, the stage 300 is capable of movement in a back and forth direction and in a left and right direction so that any part of the substrate S may receive a laser light by the light path module 200.

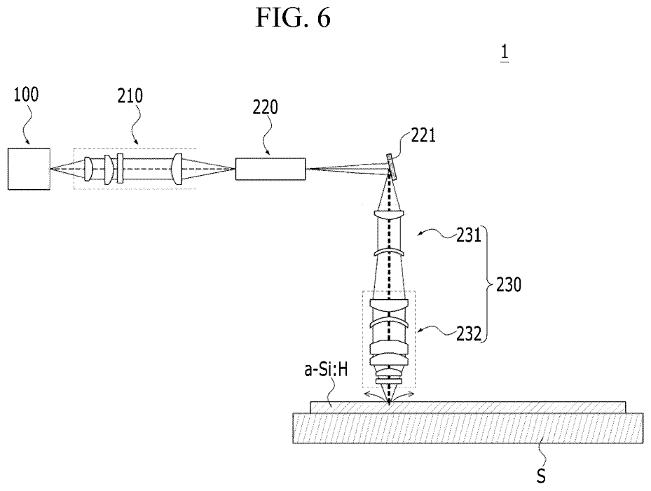

The light path module 200 includes the collimator 210, a light guide 220, a mirror 221 (see FIG. 6), and a projection lens module 230. The collimator 210 serves to convert the light emitted from the output fiber 120 into a parallel ray.

The light guide 220 serves to mix the light emitted from the collimator 210 as uniformly as possible, and the mirror 221 is preferably configured as a polarization mirror and serves to totally reflect or partially pass and partially reflect the light emitted from the light guide 220 according to its inclination angle.

The projection lens module 230 collects the light reflected from the mirror 221, focuses the light on a specific point, maximizes a light energy, and performs a dehydrogenation process and a crystallization process on the amorphous silicon on the surface of the substrate S.

This will be described below.

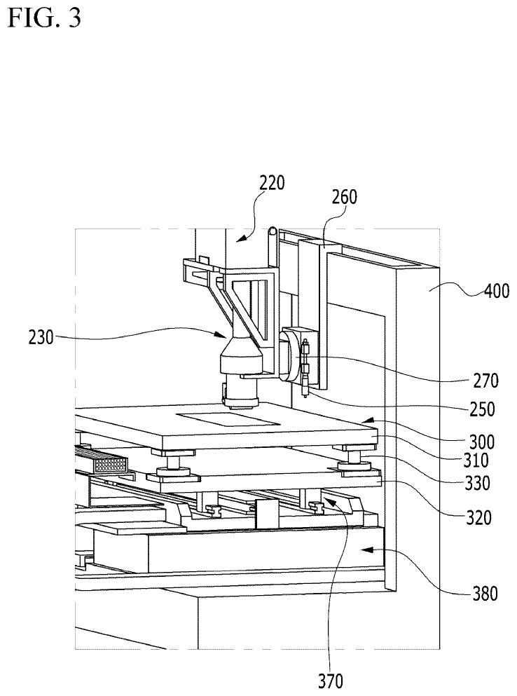

A support frame 400 (see FIG. 3) capable of supporting the light path module 230 is provided at the rear of the light path module 230, and a holder 260 is disposed over the support frame 400, and an adjustment connection unit 270 is provided on a lower front surface of the holder 260 so that the light path module 200 is connected and fixed to the adjustment connection unit 270.

The adjustment connection unit 270 is provided with an adjustment module capable of adjusting the position of the light path module 200 with respect to the support frame 400 so that the adjustment module may adjust the fine position of the support frame 400 in the front and back direction and in an up and down direction.

It is preferable that an air cooler 240 is provided at a lower end of the projection lens module 230 to quickly remove smoke or heat generated in the dehydrogenation process and the crystallization process by using air.

Meanwhile, a focus unit 250 is provided on one side of the adjustment connection unit 270 to focus the substrate S. The position of the stage 300 may be adjusted by a control unit (not shown) or the position of the light path module 200 may be adjusted by the adjustment connection unit 270 so as to be focused.

On the other hand, the light guide 220 of the light path module 200 is configured to have the exterior in the form of an enclosure, and a horizontal support plate 280 and a vertical support 290 are provided to support the exterior.

The stage 300 is configured as an upper plate 310 and a lower plate 320, and the upper plate 310 and the lower plate 320 are connected while maintaining a spaced state in the up and down direction by a connection bridge 330.

A first wire guard 350 disposed in the front and back direction and a second wire guard 360 disposed in the left and right direction are provided in the stage 300.

The first wire guard 350 is configured as a flexible material and structure that guide a first wire module supplying a signal and power to move along with the stage 300 when the stage 300 moves forward and backward and protect the first wire module. The second wire guard 360 is configured as a flexible material and structure that guide a second wire module to move along with the stage 300 when the stage 300 moves left and right and protect the second wire module.

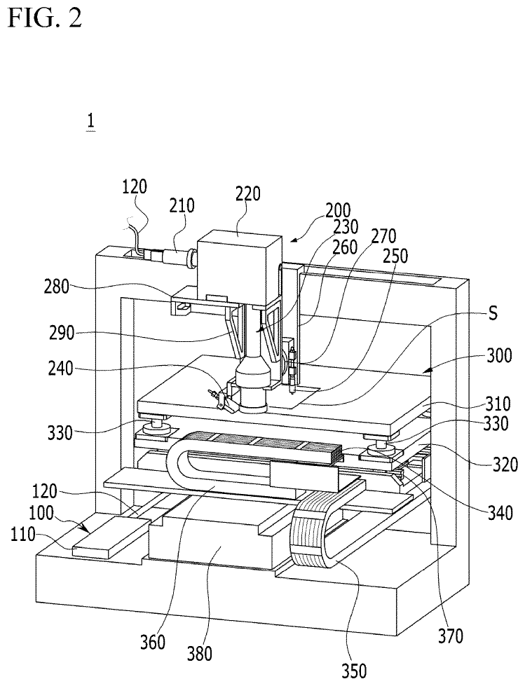

FIG. 1 illustrates the stage 300 moving forward and the substrate S located below the projection lens module 230, and FIG. 2 illustrates a state where the stage 300 moves backward and the substrate S is located behind the projection lens module 230 while the housing 110 and the output fiber 120 of the laser controller 100 are generally exposed to the outside.

The laser controller 100 and the output fiber 120 may be replaced or a maintenance work may be performed in a state where the housing 110 and the output fiber 120 of the laser controller 100 are generally exposed to the outside.

The stage 300 may move not only in the back and forth direction but also in the left and right direction.

As shown in FIG. 3, a first stage actuator 370 guiding a movement in the left and right direction is provided below the lower plate 320, and a second stage actuator 380 guiding a movement in the back and forth direction is provided below the first stage actuator 370.

It is preferable that the first and second stage actuators 370 and 380 are configured as a rail and a motor inserted into the rail and moving.

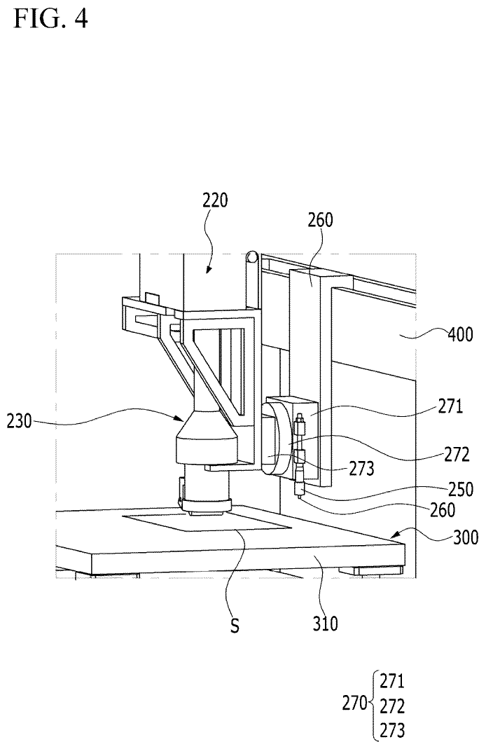

As shown in FIG. 4, the focus unit 250 is configured in a cylindrical shape disposed in a vertical direction, and a focus lens 260 is provided below the focus unit 250 to focus the substrate S.

The adjustment connection unit 270 includes a first block 271 protruding from the front of a lower end of the holder 260, an adjustment dial 272 disposed in front of the first block 271, and a second block 273 disposed in front of the adjustment dial 272, and may adjust the overall height of the light path module 200 by adjusting the adjustment dial 272.

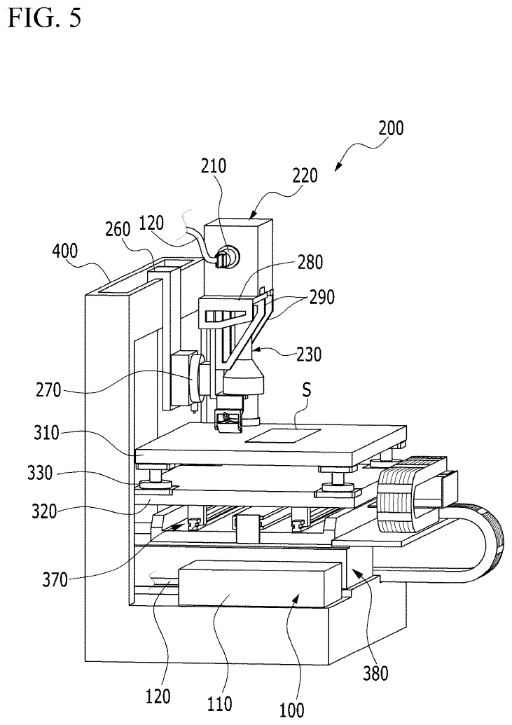

As shown in FIG. 5, the laser controller 100 includes the housing 110 constituting the exterior, and the output fiber 120 connected to the housing 110 and connected to the collimator 210.

Since the laser controller 100 is disposed next to the second stage actuator 380 and spaced apart from the stage 300 above, it is easy to access, and thus, replacement and repair may be easily performed.

In addition, since the laser controller 100 is disposed next to the second stage actuator 380, it is easy to mount the laser controller 100, and it is also easy to connect the output fiber 120 to the collimator 210. Along with the advantage of ease of installation, when the output fiber 120 is a thick single fiber, it has the advantage of securing the uniformity of light energy compared to the technology implemented in a plurality of thin fibers in the related art.

FIG. 6 is a diagram for explaining a dehydrogenation process of annealing equipment according to a first embodiment.

According to the first embodiment, light emitted from the laser controller 100 is reflected by the mirror 221 through the collimator 210 and the light guide 220. In the dehydrogenation process, an inclination angle of the mirror 221 with respect to the substrate S may be close to vertical. The mirror 221 is preferably configured as a polarization mirror.

It is preferable that an actuator (not shown) is provided in the mirror 221 to adjust the inclination angle.

When the inclination angle of the mirror 221 is large (e.g., 75°), total reflection does not occur, part of light passes through the mirror 221, and only part of the light is reflected. The reflected light is incident on an amorphous silicon substrate through the first projection lens module 231 and the second projection lens module 232.

An amorphous silicon layer on the substrate S includes hydrogen (a-Si:H), and when the hydrogen is not removed and the crystallization process is performed, the hydrogen may explode and cause a burning phenomenon, and thus, the hydrogen needs to be removed.

In the related art, to remove hydrogen, a process of removing the hydrogen by putting a substrate in a furnace and heating the substrate for about 2 hours was performed, but in the present embodiment, the substrate is heated by using a blue laser beam, and thus, the dehydrogenation process may be performed by using the annealing equipment even without utilizing the furnace.

When the dehydrogenation process is performed, the energy of a laser beam emitted from the projection lens module 230 has, for example, a temperature of 490° C. at an output of 5.2 W, and when the blue laser beam of the above output and energy is intensively irradiated onto amorphous silicon including hydrogen, a dehydrogenation phenomenon occurs.

In that state, a stage is moved to perform a crystallization process on a part where the dehydrogenation process has been completed.

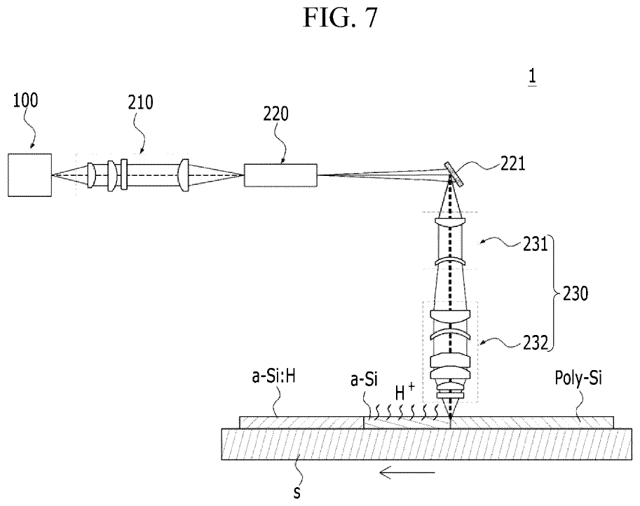

FIG. 7 is a diagram for explaining a crystallization process of annealing equipment according to the first embodiment.

That is, as shown in FIG. 7, the actuator of the mirror 221 is driven to adjust an inclination angle of the mirror 221 so that the inclination angle is lower than an angle (e.g., 45°) when a dehydrogenation process is performed.

In this case, while total reflection occurs, light is wholly reflected, and accordingly, energy may increase, and such a light is incident on a dehydrogenated amorphous silicon layer passes through the first and second projection lens modules 231 and 232.

When the crystallization process is performed, the energy of a laser light emitted from the projection lens module 230 has, for example, a temperature of 952° C. at an output of 7.4 W, and when a beam of blue laser light of the above output and energy is intensively irradiated onto amorphous silicon from which hydrogen has been removed, the crystallization process is performed and the amorphous silicon becomes polysilicon.

Here, a thickness of a semiconductor layer configured as the amorphous silicon may be 50 nm to 300 nm.

A crystallization type of the semiconductor layer may be different according to a scan speed, and a crystallized grain size may be different according to the crystallization type of the semiconductor layer.

For example, when a scan speed of the blue laser beam is about 20 mm/sec to about 50 mm/sec, full melting crystallization in which amorphous silicon is completely melted and crystallized may be performed, when the scan speed of the blue laser beam is about 50 mm/sec to about 130 mm/sec, partial melting crystallization in which amorphous silicon is partially melted and crystallized may be performed, and even when the scan speed of the blue laser beam is faster than about 130 mm/sec, solid phase crystallization (SPC) of amorphous silicon may be performed.

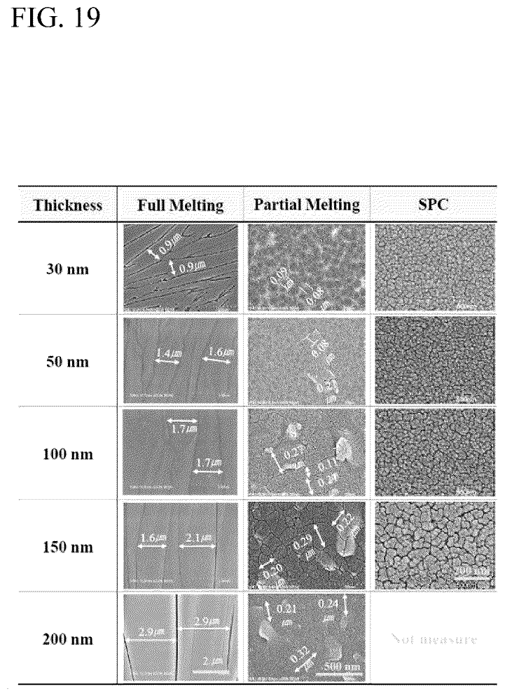

As such, in the case of using the blue laser, crystallization of amorphous silicon may be well performed even at a relatively high scan speed. A full melting crystallized grain size, a partial melting crystallized grain size, and a SPC grain size may be different from each other (see FIG. 19).

Since a blue laser absorption depth of the amorphous silicon layer reaches about 200 nm, it is possible to melt a semiconductor layer having a thickness of about 50 nm to about 300 nm through a short irradiation time, and a radius of a polycrystalline grain formed thereby is also great.

Therefore, during annealing, protrusions of a polycrystalline grain boundary that may be formed on a surface of the semiconductor layer are not formed or the number thereof is relatively small. In addition, the blue laser has high uniformity of the laser beam, thereby simultaneously melting a silicon layer of a great width at a high speed.

The semiconductor layer may be annealed without damaging a substrate surface to complete the semiconductor layer including polycrystalline silicon, and form a flat semiconductor layer without a protrusion on the surface of the semiconductor layer that may be formed on the polycrystalline grain boundary.

In the case of the first embodiment shown in FIGS. 6 and 7, one laser controller 100 and one light path module 200 are provided, and the dehydrogenation process and the crystallization process may be sequentially performed by adjusting the inclination angle of the mirror 221 and the position of the substrate S.

That is, the temperature and output of the laser beam output by setting the inclination angle of the mirror 221 to a relatively large inclination angle are set to be relatively low, hydrogen is firstly removed from amorphous silicon by irradiating the laser beam onto the semiconductor layer, and then performed by a predetermined distance.

And, again, with respect to a dehydrogenated region, a process of setting the temperature and output of the laser beam output by setting the inclination angle of the mirror 221 to a relatively small inclination angle to be relatively high, firstly crystallizing amorphous silicon by irradiating the laser beam onto the semiconductor layer and converting the amorphous silicon into polysilicon is performed.

In the case of FIGS. 6 and 7, when the dehydrogenation process is completed with respect to a specific line by proceeding the dehydrogenation process along a certain line, it is preferable to perform the crystallization process by returning to the line in reverse.

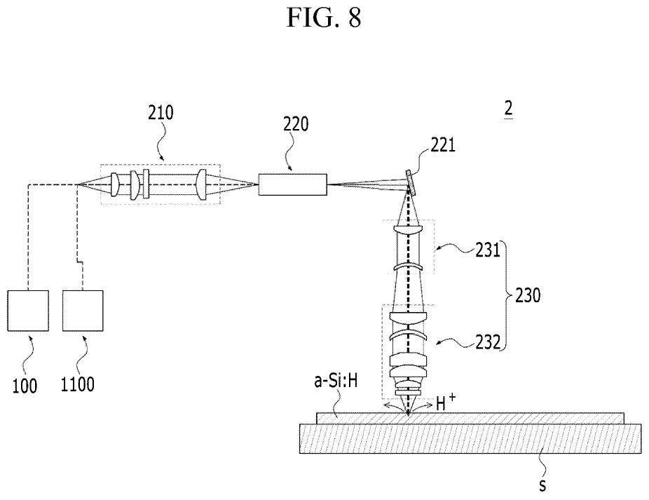

FIG. 8 is a diagram for explaining a dehydrogenation process of annealing equipment according to a second embodiment.

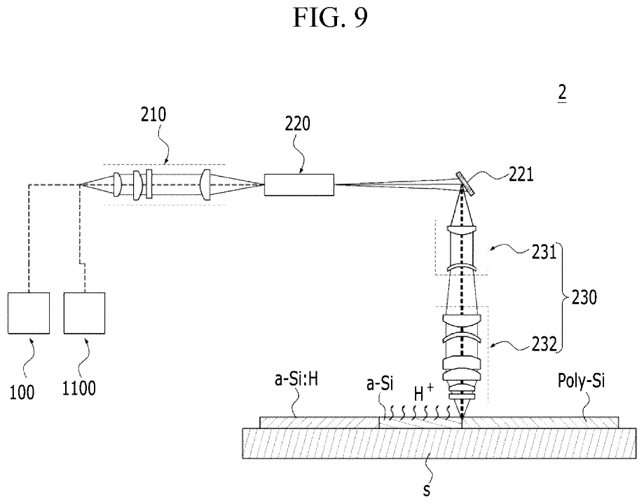

FIG. 9 is a diagram for explaining a crystallization process of the annealing equipment according to the second embodiment.

As shown in FIGS. 8 and 9, annealing equipment 2 according to the second embodiment includes two laser controllers 100 and 1100 and one light path module 200.

Any one of the two laser controllers 100 and 1100 is defined as the first laser controller 100 providing a high output, and the other is defined as the second laser controller 1100 providing a low output.

The first laser controller 100 is a controller that outputs a laser beam for performing the crystallization process, and the second laser controller 1100 is a controller that outputs a laser beam for performing the dehydrogenation process.

For example, the first laser controller 100 may be a high output laser controller equipped with 8 blue laser diodes of 10 W and having an output of 80 W, and the second laser controller 1100 may be a low output laser controller equipped with 4 blue laser diodes of 5 W and having an output of 20 W.

However, the quantity or output of blue laser diodes is not limited thereto and may be combined in various ways.

According to the second embodiment, light emitted from the second laser controller 1100 is reflected by the mirror 221 through the collimator 210 and the light guide 220. The mirror 221 maintains a large inclination angle in which an inclination of an angle of the mirror 221 is close to a vertical state, and the mirror 221 is preferably configured as a polarization mirror.

It is preferable that an actuator (not shown) is provided in the mirror 221 to adjust the inclination angle.

When the inclination angle of the mirror 221 is large (e.g., 75°), total reflection does not occur, part of light passes through the mirror 221, and only part of the light is reflected. The reflected light is incident on an amorphous silicon substrate through the first projection lens module 231 and the second projection lens module 232.

An amorphous silicon layer on the substrate S includes hydrogen (a-Si:H), and when the hydrogen is not removed and the crystallization process is performed, the hydrogen may explode and cause a burning phenomenon, and thus, the hydrogen needs to be removed.

When the dehydrogenation process is performed, the energy of a laser beam emitted from the projection lens module 230 has, for example, a temperature of 490° C. at an output of 5.2 W, and when the blue laser beam of the above output and energy is intensively irradiated onto amorphous silicon including hydrogen, a dehydrogenation phenomenon occurs.

In that state, a stage is moved to perform a crystallization process on a part where the dehydrogenation process has been completed.

As shown in FIG. 9, after moving the part where the dehydrogenation process has been completed, the crystallization process is prepared.

The light emitted from the first laser controller 100 is reflected by the mirror 221 through the collimator 210 and the light guide 220.

The actuator of the mirror 221 is driven to adjust the inclination angle of the mirror 221 so that the inclination angle is lower than an angle (e.g., 45°) when the dehydrogenation process is performed.

In this case, while total reflection occurs, the light is wholly reflected, and accordingly, energy may increase, and such a light is incident on a dehydrogenated amorphous silicon layer through the first and second projection lens modules 231 and 232.

When the crystallization process is performed, the energy of a laser light emitted from the projection lens module 230 has, for example, a temperature of 952° C. at an output of 7.4 W, and when a beam of blue laser light of the above output and energy is intensively irradiated onto amorphous silicon from which hydrogen has been removed, the crystallization process is performed and the amorphous silicon becomes polysilicon.

Here, a thickness of a semiconductor layer configured as the amorphous silicon may be 50 nm to 300 nm.

A crystallization type of the semiconductor layer may be different according to a scan speed of the blue laser beam, and a crystallized grain size may be different according to the crystallization type of the semiconductor layer.

In the case of FIGS. 8 and 9, when the dehydrogenation process is completed with respect to a specific line by proceeding the dehydrogenation process along a certain line, it is preferable to perform the crystallization process by returning to the line in reverse.

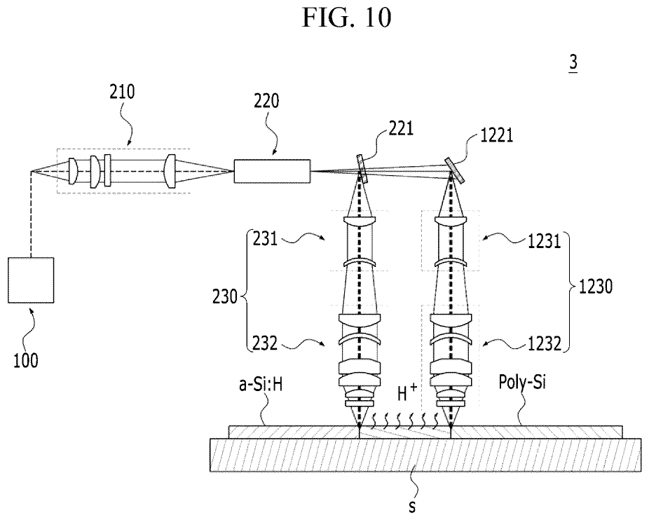

FIG. 10 is a diagram for explaining a dehydrogenation process and a crystallization process of annealing equipment according to a third embodiment.

As shown in FIG. 10, annealing equipment 3 according to the third embodiment may include one laser controller 100, two mirrors 221 and 1221, and two projection modules 230 and 1230.

The annealing equipment 3 may also be expressed as including one laser controller and two light path modules. In this case, the two light path modules commonly use the collimator 210 and the light guide 220.

In the third embodiment, a single laser controller having an output of 80 W in which 8 blue laser diodes having an output of 10 W are disposed is proposed. However, the output and quantity are not limited thereto and may be varied.

According to the third embodiment, light emitted from the laser controller is reflected by the first mirror 221 through the collimator 210 and the light guide 220, and part of the light is directed to the second mirror 1221 through the first mirror 221.

The first mirror 221 maintains a large inclination angle in which an inclination of an angle of the first mirror 221 is close to a vertical state, and the first mirror 221 is preferably configured as a polarization mirror.

It is preferable that an actuator (not shown) is provided in the first mirror 221 to adjust the inclination angle, but, in the third embodiment, the angle of the first mirror 221 may be fixed.

When the inclination angle of the first mirror 221 is large (e.g., 75°), total reflection does not occur, part of light passes through the first mirror 221 and is directed to the second mirror 1221, and only part of the light is reflected. The reflected light is incident on an amorphous silicon substrate through the first projection lens module 231 and the second projection lens module 232.

When the dehydrogenation process is performed, the energy of a laser beam emitted from the projection lens module 230 has, for example, a temperature of 490° C. at an output of 5.2 W, and when the blue laser beam of the above output and energy is intensively irradiated onto amorphous silicon including hydrogen, a dehydrogenation phenomenon occurs.

When a stage is moved in that state, since a second light path module 1200 is disposed right next to a first light path module, the crystallization process may be performed at an adjacent location as soon as the dehydrogenation process is completed.

That is, an angle (e.g., 45°) of the second mirror 1221 is lower than the angle of the first mirror 221 when the dehydrogenation process is performed.

In this case, while total reflection occurs, the light is wholly reflected, and accordingly, energy may increase, and such a light is incident on a dehydrogenated amorphous silicon layer through first and second projection lens modules 1231 and 1232.

When the crystallization process is performed, the energy of a laser light emitted from the projection lens module 1230 has, for example, a temperature of 952° C. at an output of 7.4 W, and when a beam of blue laser light of the above output and energy is intensively irradiated onto amorphous silicon from which hydrogen has been removed, the crystallization process is performed and the amorphous silicon becomes polysilicon.

In the case of the third embodiment shown in FIG. 10, one laser controller 100 and two light path modules 230 and 1230 are provided, and the dehydrogenation process and the crystallization process may be sequentially performed by adjusting the inclination angles of the first mirror 221 and the second mirror 1221 and the position of the substrate S.

That is, the output of the laser beam output by setting the inclination angle of the first mirror 221 to a relatively large inclination angle is set to be relatively low, and thus, hydrogen is firstly removed from amorphous silicon by irradiating the laser beam onto the semiconductor layer at a relatively low temperature, and then performed by a predetermined distance.

And, again, with respect to a dehydrogenated region, a process of setting the output of the laser beam output by setting the inclination angle of the second mirror 1221 to a relatively small inclination angle to be relatively high, firstly crystallizing amorphous silicon by irradiating the laser beam onto the semiconductor layer at a relatively high temperature and converting the amorphous silicon into polysilicon is performed.

In the case of the third embodiment of FIG. 10, the dehydrogenation process and the crystallization process may be sequentially or serially performed along a certain line.

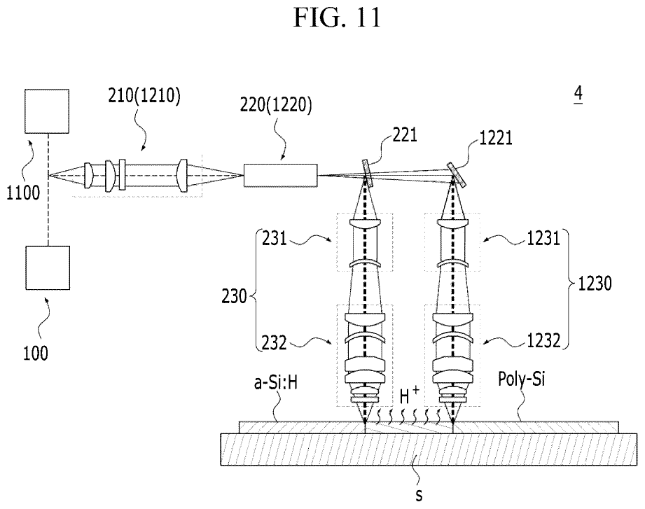

FIG. 11 is a diagram for explaining a dehydrogenation process and a crystallization process of annealing equipment according to a fourth embodiment.

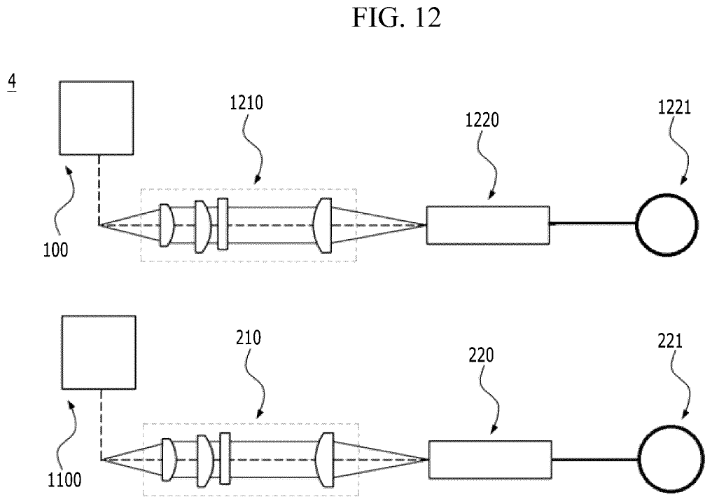

FIG. 12 is a schematic plan view of the annealing equipment according to the fourth embodiment.

As shown in FIG. 11, annealing equipment 4 according to the fourth embodiment may include two laser controllers 100 and 1100 and two light path modules 230 and 1230.

Any one of the two laser controllers 100 and 1100 is defined as the first laser controller 100 providing a high output, and the other is defined as the second laser controller 1100 providing a low output.

In the two light path modules 230 and 1230, the first light path module 230 is used for the dehydrogenation process, and the second light path module 1230 is used for the crystallization process.

For example, the first laser controller 100 may be a high output laser controller equipped with 8 blue laser diodes of 10 W and having an output of 80 W, and the second laser controller 1100 may be a low output laser controller equipped with 4 blue laser diodes of 5 W and having an output of 20 W. The quantity or output may be varied.

FIG. 11 shows on the side that the first collimator 210 and the second collimator 1210 overlap, and the first light guide 220 and the second light guide 1220 overlap. For clear understanding, FIG. 12 shows that the first collimator 210 and the second collimator 1210 are arranged side by side in parallel on a plane, and the first light guide 220 and the second light guide 1220 are arranged side by side in parallel on a plane.

In this state, the first laser controller 100 of high output is connected to the second light path module 1200 used in the crystallization process, and the second laser controller 1100 of low output is connected to the first light path module 200 used in the dehydrogenation process.

According to the fourth embodiment, light emitted from the second laser controller 1100 is reflected by the first mirror 221 through the collimator 210 and the light guide 220. The first mirror 221 maintains a large inclination angle in which an inclination of an angle of the first mirror 221 is close to a vertical state, and the first mirror 221 is preferably configured as a polarization mirror.

It is preferable that an actuator (not shown) is provided in the first mirror 221 to adjust the inclination angle, but, in the fourth embodiment, the angle of the first mirror 221 may be fixed.

When the inclination angle of the first mirror 221 is large (e.g., 75°), total reflection does not occur, part of light passes through the first mirror 221, and only part of the light is reflected.

The light reflected by the first mirror 221 is incident on an amorphous silicon substrate through the first projection lens module 231 and the second projection lens module 232 to perform the dehydrogenation process.

When the dehydrogenation process is performed, the energy of a laser beam emitted from a projection lens module has, for example, a temperature of 490° C. at an output of 5.2 W, and when the blue laser beam of the above output and energy is intensively irradiated onto amorphous silicon including hydrogen, a dehydrogenation phenomenon occurs.

While moving a stage in that state, the first laser controller 100 for the dehydrogenation process is driven so that the laser light is directed to the second mirror 1221.

Also, an angle (e.g., 45°) of the second mirror 1221 is lower than the angle of the first mirror 221 when the dehydrogenation process is performed.

In this case, while total reflection occurs, the light is wholly reflected, and accordingly, energy may increase, and such a light is incident on a dehydrogenated amorphous silicon layer through the first and second projection lens modules 1231 and 1232.

When the crystallization process is performed, the energy of a laser light emitted from the projection lens module 1230 has, for example, a temperature of 952° C. at an output of 7.4 W, and when a beam of blue laser light of the above output and energy is intensively irradiated onto amorphous silicon from which hydrogen has been removed, the crystallization process is performed and the amorphous silicon becomes polysilicon.

The annealing equipment 4 according to the fourth embodiment shown in FIGS. 11 and 12 may perform the dehydrogenation process and the crystallization process on adjacent lines different from each other on a plane.

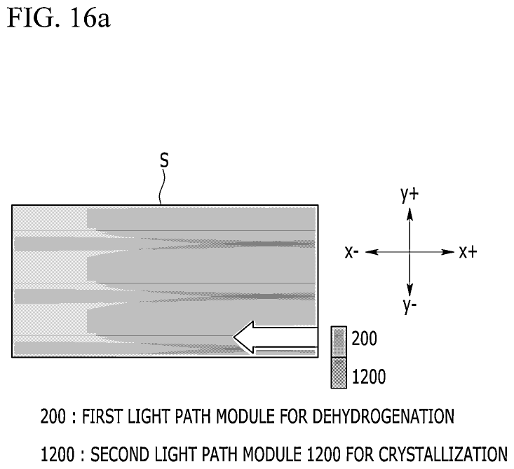

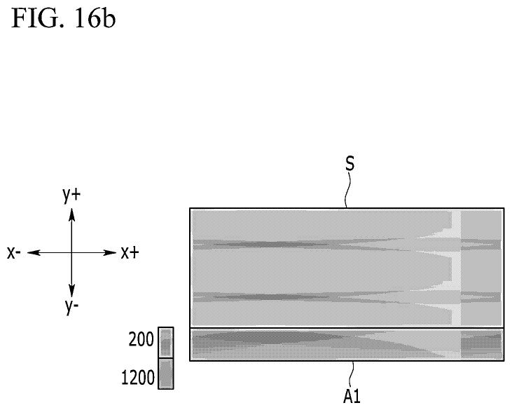

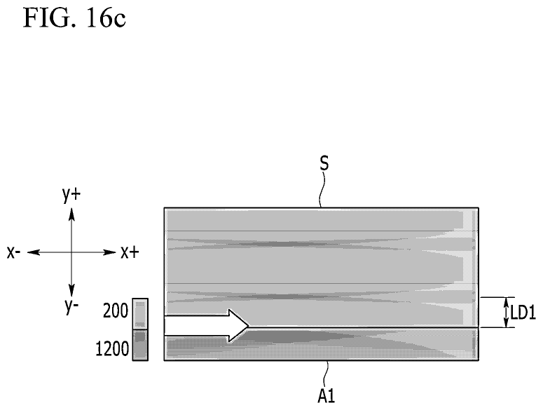

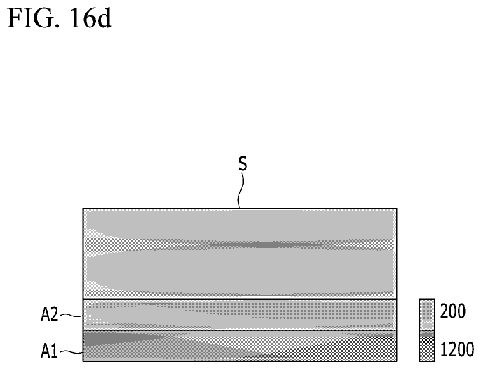

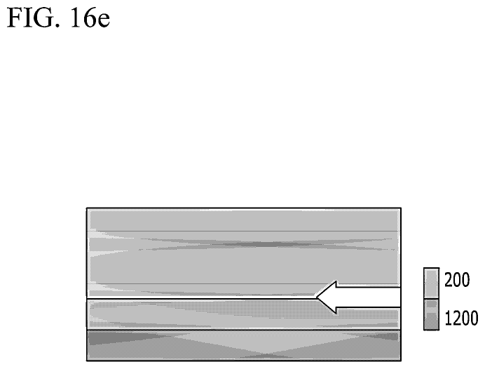

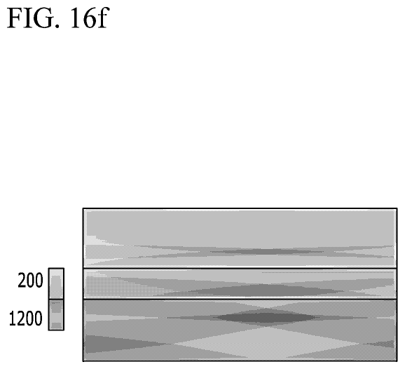

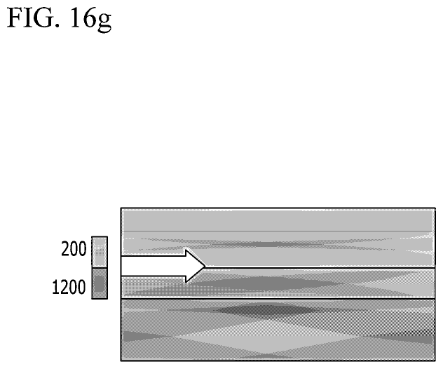

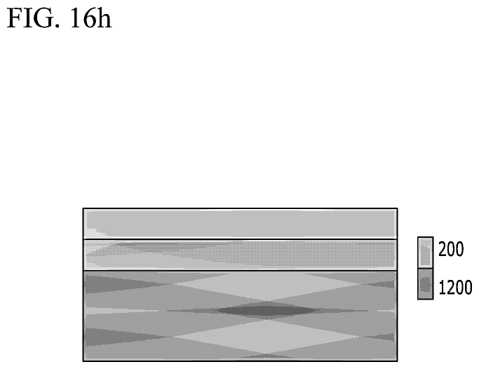

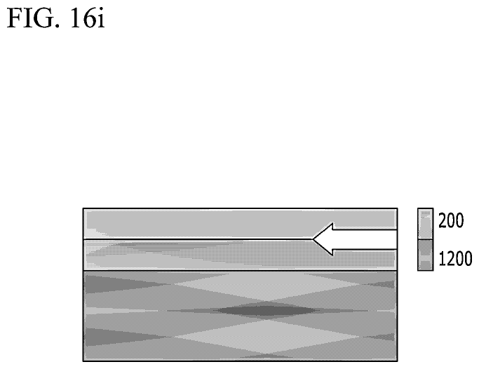

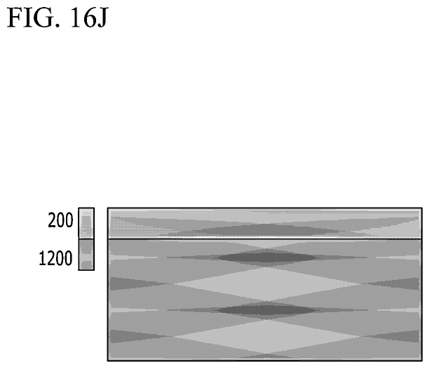

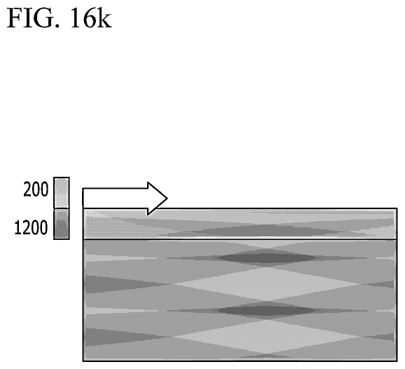

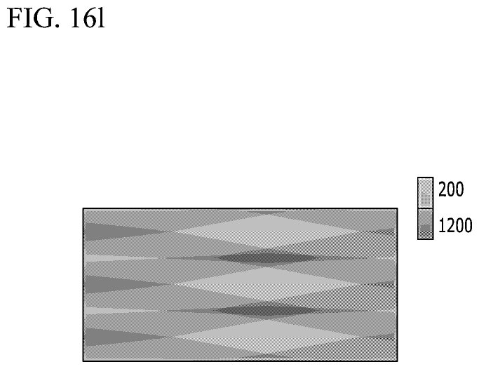

That is, when the dehydrogenation process is performed in a first line, which is a predetermined process unit, and then the dehydrogenation process on the first line is completed, the crystallization process on the first line may be performed, and simultaneously, the dehydrogenation process may be performed in a second line of a process unit parallel to the first line (see FIGS. 16a to 16l).

That is, the dehydrogenation process and the crystallization process are performed in series in the third embodiment shown in FIG. 10, whereas the dehydrogenation process and the crystallization process may be performed in parallel in the fourth embodiment shown in FIGS. 11 and 12.

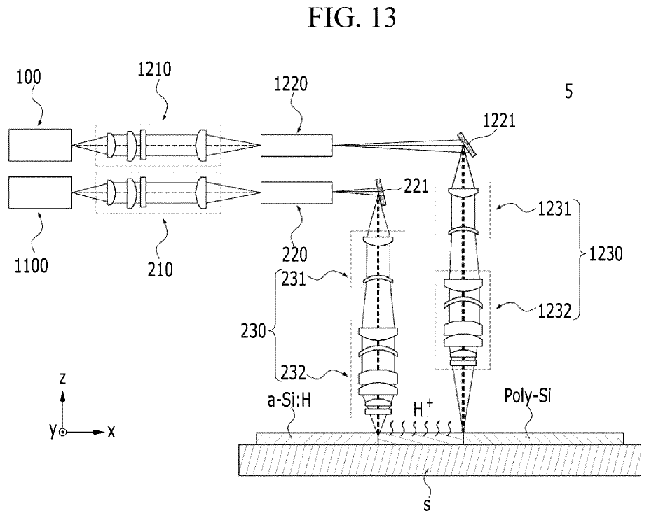

FIG. 13 is a diagram for explaining a dehydrogenation process and a crystallization process of annealing equipment according to a fifth embodiment.

Annealing equipment 5 according to the fifth embodiment shown in FIG. 13 may include two laser controllers 100 and 1100 and two light path modules 200(210, 220, 221) and 1200(1210, 1220, 1221) similarly to the fourth embodiment.

Any one of the two laser controllers 100 and 1100 is defined as the first laser controller 100 providing a high output, and the other is defined as the second laser controller 1100 providing a low output.

In the two light path modules 200 and 1200, the first light path module 200 is used for the dehydrogenation process, and the second light path module 1200 is used for the crystallization process.

For example, the first laser controller 100 may be a high output laser controller equipped with 8 blue laser diodes of 10 W and having an output of 80 W, and the second laser controller 1100 may be a low output laser controller equipped with 4 blue laser diodes of 5 W and having an output of 20 W. However, the quantity or output may be varied.

FIG. 11 shows on the side that the first collimator 210 and the second collimator 1210 overlap, and the first light guide 220 and the second light guide 1220 overlap, but FIG. 12 shows that the first collimator 210 and the second collimator 1210 are arranged side by side in parallel on a plane, and the first light guide 220 and the second light guide 1220 are arranged side by side in parallel on a plane.

In the fifth embodiment of FIG. 13, the first light path module 200 and the second light path module 1200 are disposed along with the z-axis.

In this state, the first laser controller 100 of high output is connected to the second light path module 1200 used in the crystallization process, and the second laser controller 1100 of low output is connected to the first light path module 200 used in the dehydrogenation process.

According to the fifth embodiment, light emitted from the second laser controller 1100 is reflected by the first mirror 221 through the collimator 210 and the light guide 220. The first mirror 221 maintains a large inclination angle in which an inclination of an angle of the first mirror 221 is close to a vertical state, and the first mirror 221 is preferably configured as a polarization mirror.

It is preferable that an actuator (not shown) is provided in the first mirror 221 to adjust the inclination angle, but, in the fifth embodiment, the angle of the first mirror 221 may be fixed.

When the inclination angle of the first mirror 221 is large (e.g., 75°), total reflection does not occur, part of light passes through the first mirror 221, and only part of the light is reflected.

The light reflected by the first mirror 221 is incident on an amorphous silicon substrate through the first projection lens module 231 and the second projection lens module 232.

When the dehydrogenation process is performed, the energy of a laser beam emitted from a projection lens module has, for example, a temperature of 490° C. at an output of 5.2 W, and when the blue laser beam of the above output and energy is intensively irradiated onto amorphous silicon including hydrogen, a dehydrogenation phenomenon occurs.

While moving a stage in that state, the first laser controller 100 for the dehydrogenation process is driven. In this state, light is wholly directed to the second mirror 1221.

Also, an angle (e.g., 45°) of the second mirror 1221 is lower than the angle of the first mirror 221 when the dehydrogenation process is performed.

In this case, while total reflection occurs, the light is wholly reflected, and accordingly, energy may increase, and such a light is incident on a dehydrogenated amorphous silicon layer through the first and second projection lens modules 1231 and 1232.

When the crystallization process is performed, the energy of a laser light emitted from the projection lens module 1230 has, for example, a temperature of 952° C. at an output of 7.4 W, and when a beam of blue laser light of the above output and energy is intensively irradiated onto amorphous silicon from which hydrogen has been removed, the crystallization process is performed and the amorphous silicon becomes polysilicon.

In the fifth embodiment shown in FIG. 13, the dehydrogenation process and the crystallization process may be performed on the same line on a x-y plane.

That is, the dehydrogenation process is performed in a first line, and then the dehydrogenation process on the first line is completed, the crystallization process on the first line may be performed, and simultaneously, the dehydrogenation process may be performed in a second line at a different location extending from the first line.

That is, the dehydrogenation process and the crystallization process may be performed in parallel in the fourth embodiment shown in FIGS. 11 and 12, whereas the dehydrogenation process and the crystallization process are performed in series in the fifth embodiment shown in FIG. 13.

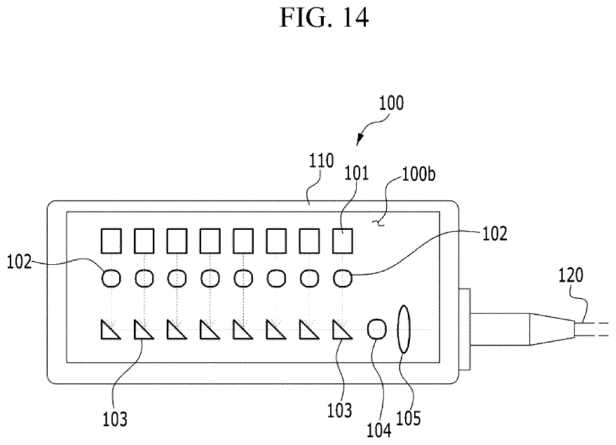

FIG. 14 is a schematic diagram of a blue laser diode controller.

The laser controller 100 includes the controller housing 110, a plurality of blue laser diodes 101 provided in an inner space of a controller housing 100a, a first focus lens 102 disposed in front of each blue laser diode 101, a prism lens 103 reflecting or transmitting light emitted from the first focus lens 102, a second focus lens 104 focusing the light reflected from the prism lens 103 and merged, and an image lens 105 guiding the light emitted from the second focus lens 104 to the output fiber 120.

The laser controller 100 shown in FIG. 14 shows a first laser controller of high output, but a structure of a second laser controller of a low output is similar to that of the first laser controller, and only the quantity and output of blue laser diodes 101 and the quantity of each lens are different.

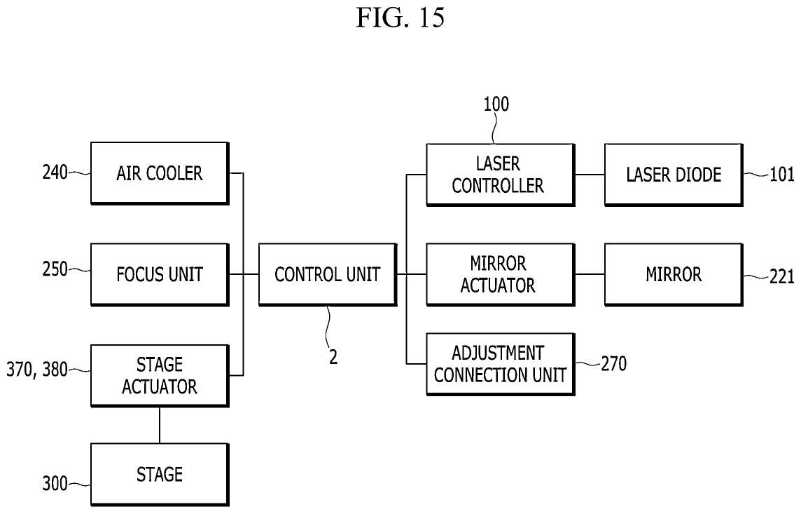

FIG. 15 is a control block diagram of the present embodiment.

A control unit 2 generally controlling an annealing device according to the present embodiment is provided. The control unit 2 controls the laser controller 100, a mirror actuator 221a, the air cooler 240, the focus unit 250, and the stage actuators 370 and 380.

The laser controller 100 controls an output of the laser diode 101, the mirror actuator 221a adjusts an angle of the mirror 221 to perform a dehydrogenation process or a crystallization process as described above, and the stage actuators 370 and 380 serve to control the stage 300 in front and rear and left and right directions to adjust a position of a substrate.

FIGS. 16a to 16l show that a dehydrogenation process and a crystallization process are performed in an embodiment in which two light path modules are present.

As shown in FIG. 16a, in a state where a hydrogenated amorphous silicon layer is placed on the substrate S, the substrate S moves in an x+ direction with respect to the first light path module 200 for dehydrogenation and the second light path module 1200 for crystallization. Then, it is as if the light path modules move in an x-direction as indicated by an arrow shown in the drawing. In an embodiment, it may be implemented as if the light path modules move in the x-direction by moving a stage on which the substrate S is placed in the x+ direction. Here, the first light path module 200 and the second light path module 1200 may be disposed in parallel.

As shown in FIG. 16b, first, dehydrogenation may be performed on an area A1 by the first light path module 200.

After the dehydrogenation process on the area A1, the substrate S is moved by a predetermined one line distance LD1 in a y-direction, and as shown in FIG. 16c, the second light path module 1200 is located in correspondence to the area A1 of the substrate S, and the first light path module 200 is located above the area A1 by the one line distance LD1 in a y+ direction.

In this state, when the process is performed in a direction of an arrow shown in FIG. 16c, as shown in FIG. 16d, the dehydrogenated area A1 in FIG. 16b is crystallized, and a dehydrogenation process is performed on an area A2 which is located above the area A1 by the one line distance LD1.

And again, when the substrate S moves by the one line distance LD1 in the y-direction, as shown in FIG. 16e, the dehydrogenation process and the crystallization process are performed in a direction of an arrow. As shown in FIGS. 16f to 16k, when the dehydrogenation process and the crystallization process are repeated in directions of arrows, the crystallization process may be subsequently performed on the area on which the dehydrogenation process has been completed. Finally, as shown in FIG. 161, the dehydrogenation process and the crystallization process may be generally completed.

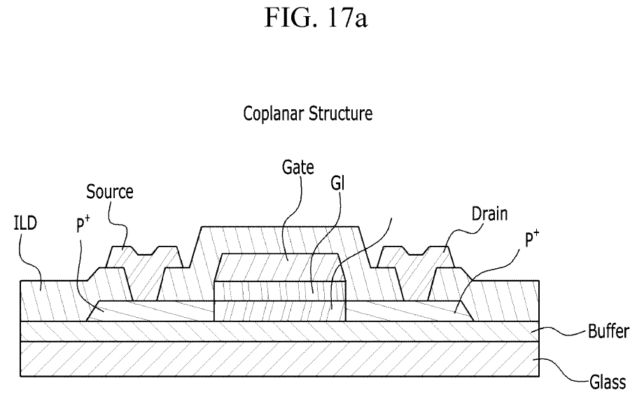

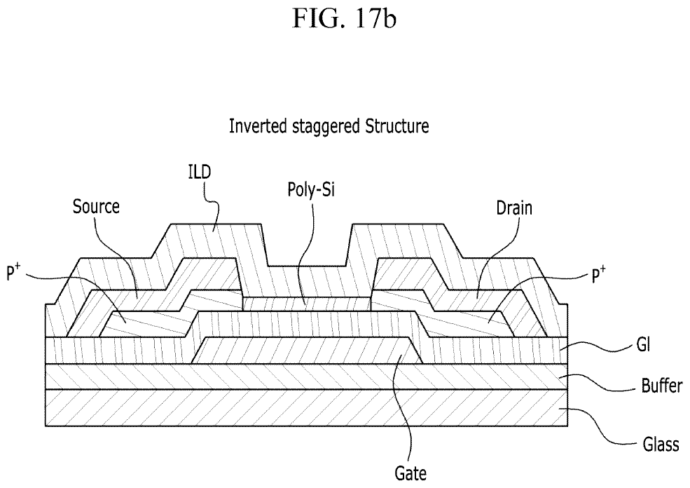

FIG. 17a is a diagram illustrating an example of a thin film transistor including a semiconductor layer crystallized according to the present embodiment.

FIG. 17a is a cross-sectional view of the thin film transistor having a coplanar structure.

In the case of the coplanar structure as shown in FIG. 17a, noise may not be generated because a gate electrode and a source electrode, and the gate electrode and a drain electrode do not overlap in a vertical direction. The source electrode or the drain electrode may be an input electrode, and the other may be an output electrode.

FIG. 17b is a diagram illustrating another example of a thin film transistor including a semiconductor layer crystallized according to the present embodiment.

FIG. 17b is a diagram showing a cross-sectional view of the thin film transistor having an inverted staggered structure.

As shown in FIG. 17b, in the case of the inverted staggered structure, a gate electrode and a source electrode, and the gate electrode and a drain electrode slightly overlap each other in a vertical direction, but there is an advantage in that a charge capacity is large. The source electrode or the drain electrode may be an input electrode, and the other may be an output electrode.

To form a polycrystalline semiconductor layer of each of two structures, in the related art, after a dehydrogenation process of heating the polycrystalline semiconductor layer at a temperature of 450° C. for about 2 hours in a furnace is performed, a crystallization process is performed. However, in the present embodiments, the dehydrogenation process in the furnace is omitted, and the dehydrogenation process and the crystallization process may be sequentially performed by adjusting the temperature and power of a blue laser beam in one annealing equipment.

In addition, in the process according to the present embodiments, there is an advantage that the substrate S or a gate insulator GI is not adversely affected thermally.

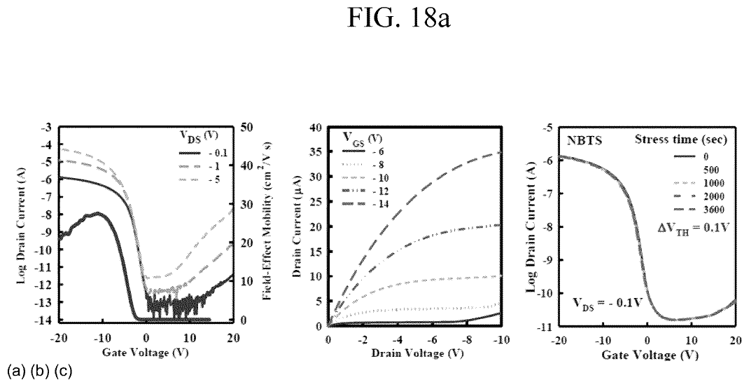

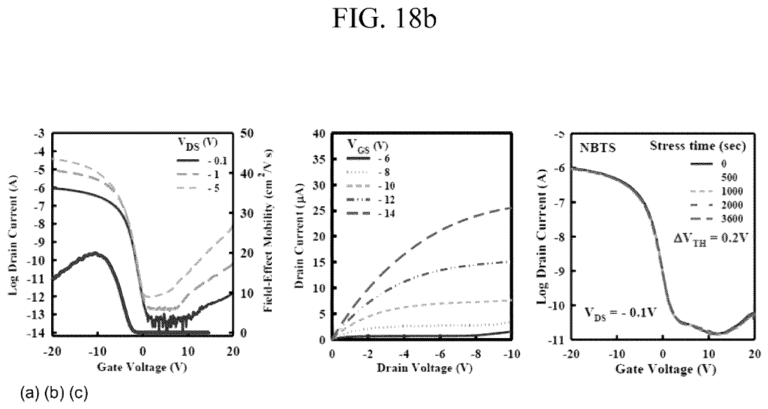

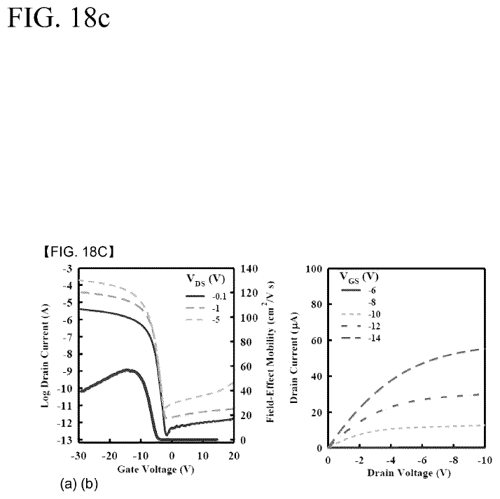

FIG. 18a is a characteristic graph of a thin film transistor including a semiconductor layer manufactured according to a comparative example heated at 450° C. for 2 hours in a furnace.

Graph (a) of FIG. 18a is a graph obtained by measuring transfer characteristics by turning on the thin film transistor while changing a gate voltage at a drain-source voltage VDS of each of −0.1 V, −1 V, and −5 V. Graph (b) of FIG. 18a is the characteristic graph of a drain current according to a drain voltage of the thin film transistor at each of a plurality of gate-source voltages VGS. Graph (c) of FIG. 18a is a drain current characteristic graph according to a gate voltage at each of a plurality of stress times. A negative bias temperature stress (NBTS) is performed at a drain-source voltage of −0.1 V, and a characteristic curve at a stress time of each of 0 sec, 500 sec, 1000 sec, 2000 sec, and 3600 sec, is shown as graph (c) of FIG. 18a. As shown in graph (c) of FIG. 18a, a change of a threshold voltage is 0.1 V.

FIG. 18b is a characteristic graph of a coplanar structure thin film transistor including a semiconductor layer manufactured according to the present embodiment.

Graph (a) of FIG. 18b is a graph obtained by measuring transfer characteristics by turning on the thin film transistor while changing a gate voltage at the drain-source voltage VDS of each of −0.1 V, −1 V, and −5 V. Graph (b) of FIG. 18b is the characteristic graph of a drain current according to a drain voltage of the thin film transistor at each of a plurality of gate-source voltages VGS. Graph (c) of FIG. 18b is a drain current characteristic graph according to a gate voltage at each of a plurality of stress times. An NBTS is performed at a drain-source voltage of −0.1 V, and a characteristic curve at a stress time of each of 0 sec, 500 sec, 1000 sec, 2000 sec, and 3600 sec, is shown as graph (c) of FIG. 18b. As shown in graph (c) of FIG. 18b, a change of a threshold voltage is 0.2 V.

FIG. 18c is a characteristic graph of an inverted staggered structure thin film transistor including a semiconductor layer manufactured according to the present embodiment.

Graph (a) of FIG. 18c is a graph obtained by measuring transfer characteristics by turning on the thin film transistor while changing a gate voltage at the drain-source voltage VDS of each of −0.1 V, −1 V, and −5 V. Graph (b) of FIG. 18c is the characteristic graph of a drain current according to a drain voltage of the thin film transistor at each of a plurality of gate-source voltages VGS.

FIG. 18c shows a graph (first) obtained by measuring the transfer characteristics and a graph (second) of output characteristics of the thin film transistor having a structure including the semiconductor layer manufactured according to the present embodiment.

As shown in FIGS. 18a to 18c, there is almost no difference in performance between the thin film transistor manufactured according to the related art and the thin film transistor manufactured according to the present embodiments, and thus, the reliability and durability of the thin film transistor manufactured according to the present embodiment may be equivalent to the reliability and durability according to the related art.

On the other hand, even in the case of other specifications, the performance is almost the same in the related art and the present embodiments as shown in Table 1 below.

TABLE 1

| | Mobility | VTH | SS | Stability |
|---|---|---|---|---|
| Category | (Cm²/Vs) | (V) | (V/Dec.) | (ΔV_{TH}) |
| Related Art | 27.6 | −1.3 | 0.67 | 0.1 |
| Present | 20.0 | −0.9 | 0.70 | 0.2 |
| Embodiment | | | | |

As described above, the present disclosure has been described with reference to the embodiments shown in the drawings, but this is only for explaining the present disclosure, and it will be understood by those skilled in the art to which the present disclosure belongs that various modifications or equivalent embodiments are possible from the detailed description of the invention.

Therefore, the true scope of the present disclosure should be determined by the technical spirit of the claims.

<Description of symbols>

| | |
|---|---|
| 100: laser controller | 120: output fiber |
| 200: light path module | 210: collimator |
| 220: light guide | 221: mirror |
| 230: projection lens module | 300: stage |
| 400: support frame | |

What is claimed is:

1. A blue laser annealing equipment comprising:
at least one blue laser diode controller including at least one output fiber;
at least one light path module connected to an output fiber of the blue laser diode controller to process light emitted from the output fiber and direct the light to a substrate and perform a dehydrogenation process or a crystallization process on a silicon layer applied to the substrate; and
a stage capable of relative motion with respect to the light path module and loading the substrate so that the dehydrogenation process and the crystallization process are performed on a surface of the substrate with respect to the light path module.

2. The blue laser annealing equipment of claim 1, wherein:
the blue laser diode controller includes
a controller housing;
a plurality of blue laser diodes provided in the controller housing;
a first focus lens disposed in front of each of the blue laser diodes;
a prism lens reflecting light emitted from the first focus lens;
a second focus lens focusing the light reflected from the prism lens and merged; and
an image lens guiding the light emitted from the second focus lens to the output fiber.

3. The blue laser annealing equipment of claim 1, wherein:
the light path module includes
a collimator connected to the output fiber;
a light guide connected to the collimator;
a polarization mirror reflecting light emitted from the light guide; and
a projection lens module refracting and focusing the light reflected and emitted from the polarization mirror and irradiating the light onto the substrate placed on the stage.

4. The blue laser annealing equipment of claim 3, further comprising:
a mirror actuator adjusting a reflection angle of the polarization mirror.

5. The blue laser annealing equipment of claim 3, wherein:
the blue laser diode controller is configured as one blue laser diode controller,
the light path module is also configured as one light path module, and
a reflection angle of the polarization mirror of the light path module is adjusted by an actuator.

6. The blue laser annealing equipment of claim 5, wherein:
an angle of the polarization mirror during a dehydrogenation process and an angle of the polarization mirror during a crystallization process are different from each other so that an output value and temperature of light energy from the light path module are different.

7. The blue laser annealing equipment of claim 3, wherein:
the blue laser diode controller is configured as two blue laser diode controllers,
the two laser diode controllers are configured as a first laser diode controller of a high output and a second laser diode controller of a low output, and
the light path module is configured as one light path module
so that a reflection angle of the polarization mirror of the light path module is adjusted by an actuator.

8. The blue laser annealing equipment of claim 7, wherein:
during a dehydrogenation process, light enters the light path module from the second laser diode controller of the low output to perform the dehydrogenation process on a substrate, and
during a crystallization process, light enters the light path module from the first laser diode controller of the high output to perform the crystallization process on the substrate.

9. The blue laser annealing equipment of claim 3, wherein:
the blue laser diode controller is configured as one blue laser diode controller,
the light path module is configured as two light path modules and includes a first light path module for dehydrogenation and a second light path module for crystallization, and
an inclination angle of a mirror of the first light path module is greater than an inclination angle of a mirror of the second light path module
so that a temperature and output of light energy emitted from the first light path module are lower than a temperature and power of light energy emitted from the second light path module.

10. The blue laser annealing equipment of claim 9, wherein:
a first mirror of the first light path module and a second mirror of the second light path module are disposed adjacent to each other,
light emitted from a light guide is partially reflected by the first mirror, and the remaining light moves to the second mirror through the first mirror and is reflected by the second mirror,
the light reflected from the first mirror is used in a dehydrogenation process through a first projection lens module of a first light path module, and
the light reflected from the second mirror is used in a crystallization process through a second projection lens module of a second light path module.

11. The blue laser annealing equipment of claim 3, wherein:
the blue laser diode controller is configured as two blue laser diode controllers, and the two laser diode controllers are configured as a first laser diode controller of a high output and a second laser diode controller of a low output,
the light path module is configured as two light path modules and includes a first light path module for dehydrogenation and a second light path module for crystallization,
the first laser diode controller and the second light path module are connected to each other,
the second laser diode controller and the first light path module are connected to each other, and
an inclination angle of a mirror of the first light path module is greater than an inclination angle of a mirror of the second light path module
so that a temperature and output of light energy emitted from the first light path module are lower than a temperature and power of light energy emitted from the second light path module.

12. An annealing manufacturing process using a blue laser annealing equipment, the annealing manufacturing process comprising:
outputting light from a blue laser diode controller to at least one output fiber;
performing a dehydrogenation process by reflecting the output light to a mirror and irradiating the light onto an amorphous silicon layer by controlling an inclination angle of the mirror to a first angle; and
performing a crystallization process by irradiating the output light onto an area where the dehydrogenation process has been completed by controlling the inclination angle of the mirror to a second angle.

13. The annealing manufacturing process of claim 12, wherein:
an angle of the mirror during the dehydrogenation process and an angle of the mirror during the crystallization process are different from each other so that an output value and temperature of light energy from a light path module are different.

14. The annealing manufacturing process of claim 12, wherein:
the blue laser diode controller is configured as two blue laser diode controllers,
the two laser diode controllers are configured as a first laser diode controller of a high output and a second laser diode controller of a low output, and
the light path module is configured as one light path module
so that a reflection angle of the mirror of a light path module is adjusted by an actuator.

15. The annealing manufacturing process of claim 14, wherein:
during a dehydrogenation process, light enters the light path module from the second laser diode controller of the low output to perform the dehydrogenation process on a substrate, and
during a crystallization process, light enters the light path module from the first laser diode controller of the high output to perform the crystallization process on the substrate.

16. The annealing manufacturing process of claim 12, wherein:
the blue laser diode controller is configured as one blue laser diode controller,
the light path module is configured as two light path modules and includes a first light path module for dehydrogenation and a second light path module for crystallization, and
an inclination angle of a mirror of the first light path module is greater than an inclination angle of a mirror of the second light path module
so that a temperature and output of light energy emitted from the first light path module are lower than a temperature and power of light energy emitted from the second light path module.

17. The annealing manufacturing process of claim 16, wherein:
a first mirror of the first light path module and a second mirror of the second light path module are disposed adjacent to each other,
light emitted from a light guide is partially reflected by the first mirror, and the remaining light moves to the second mirror through the first mirror and is reflected by the second mirror,
the light reflected from the first mirror is used in a dehydrogenation process through a first projection lens module of a first light path module, and
the light reflected from the second mirror is used in a crystallization process through a second projection lens module of a second light path module.

18. The annealing manufacturing process of claim 12, wherein:
the blue laser diode controller is configured as two blue laser diode controllers, and the two laser diode controllers are configured as a first laser diode controller of a high output and a second laser diode controller of a low output,
the light path module is configured as two light path modules and includes a first light path module for dehydrogenation and a second light path module for crystallization,
the first laser diode controller and the first light path module are connected to each other,
the second laser diode controller and the second light path module are connected to each other, and
an inclination angle of a mirror of the first light path module is greater than an inclination angle of a mirror of the second light path module
so that a temperature and output of light energy emitted from the first light path module are lower than a temperature and power of light energy emitted from the second light path module.
